(19) United States
(12) Patent Application Publication
(10) Pub. No.: US 2016/0372481 A1
(43) Pub. Date: Dec. 22, 2016

(54) NON-VOLATILE MEMORY DEVICE

(71) Applicant: Kabushiki Kaisha Toshiba, Minato-ku (JP)

(72) Inventors: Takashi IZUMIDA, Yokohama (JP); Masaki KONDO, Yokkaichi (JP); Tadayoshi UECHI, Kawasaki (JP)

(73) Assignee: Kabushiki Kaisha Toshiba, Minato-ku (JP)

(21) Appl. No.: 14/958,139

(22) Filed: Dec. 3, 2015

Related U.S. Application Data
(60) Provisional application No. 62/180,273, filed on Jun. 16, 2015.

(51) Int. Cl. H01L 27/115

(52) U.S. Cl. CPC H01L 27/11582; H01L 27/11556

(57) ABSTRACT

A non-volatile memory device includes a first conductive layer of a first conductivity type and a second conductive layer of a second conductivity type on the first conductive layer. The second conductor layer has a surface opposite to the first conductive layer. The device includes a first electrode layer arranged with the second conductive layer in a first direction perpendicular to the surface of the second conductive layer, a first channel body extending through the first electrode layer in the first direction, and a charge storage layer between the first electrode layer and the first channel body. The device includes a first region of the first conductivity type between the first conductive layer and the first channel body, and a conductor arranged with the first electrode in a second direction parallel to the surface of the second conductive layer. The conductor is electrically connected to the second conductive layer.

### CROSS-REFERENCE TO RELATED APPLICATIONS

This application is based upon and claims the benefit of priority from U.S. Provisional Patent Application 62/180,273 filed on Jun. 16, 2015; the entire contents of which are incorporated herein by reference.

### FIELD

Embodiments described herein relate generally to a non-volatile memory device.

### BACKGROUND

A two-dimensionally integrated memory device has a storage capacity that is restricted by a limit of refining a memory cell dimension in a semiconductor process. In order to overcome this limitation, a three-dimensionally integrated memory device is under development, in which memory cells are disposed along channels extending in a direction perpendicular to a substrate surface, for example. However, unintentional variations of the operating voltage may be found in such a memory device due to neutral threshold voltages of memory cells different from each other. The variations of the operating voltage may deteriorate the performance of the memory device by extending the data writing period or the data erasing period. Thus, there is a demand for suppressing the differences in the neutral threshold voltages of memory cells.

### BRIEF DESCRIPTION OF THE DRAWINGS

FIG. 1 is a perspective view schematically showing a non-volatile memory device according to a first embodiment;

FIGS. 2A and 2B are schematic views showing the non-volatile memory device according to the first embodiment;

FIG. 3 is a schematic sectional view showing a non-volatile memory device according to a comparative example;

FIG. 4 is a graph showing characteristics of the memory cells;

FIGS. 5A to 5H are schematic sectional views showing a manufacturing process of the non-volatile memory device according to the first embodiment;

FIG. 6 is a schematic sectional view showing a non-volatile memory device according to a second embodiment;

FIGS. 7A to 7F are schematic sectional views showing a manufacturing process of the non-volatile memory device according to the second embodiment;

FIG. 8 is a schematic sectional view showing a non-volatile memory device according to a third embodiment;

FIGS. 9A to 9K are schematic sectional views showing a manufacturing process of the non-volatile memory device according to the third embodiment; and

FIG. 10 is a schematic sectional view showing a non-volatile memory device according to a fourth embodiment.

### DETAILED DESCRIPTION

According to one embodiment, a non-volatile memory device includes a first conductive layer of a first conductivity type and a second conductive layer of a second conductivity type provided on the first conductive layer. The second conductor layer has a surface opposite to the first conductive layer. The device includes a first electrode layer arranged with the second conductive layer in a first direction perpendicular to the surface of the second conductive layer, a first channel body extending through the first electrode layer in the first direction, and a charge storage layer provided between the first electrode layer and the first channel body. The device further includes a first region of the first conductivity type provided in the second conductive layer between the first conductive layer and the first channel body, and a conductor arranged with the first electrode in a second direction parallel to the surface of the second conductive layer. The conductor is electrically connected to the second conductive layer.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

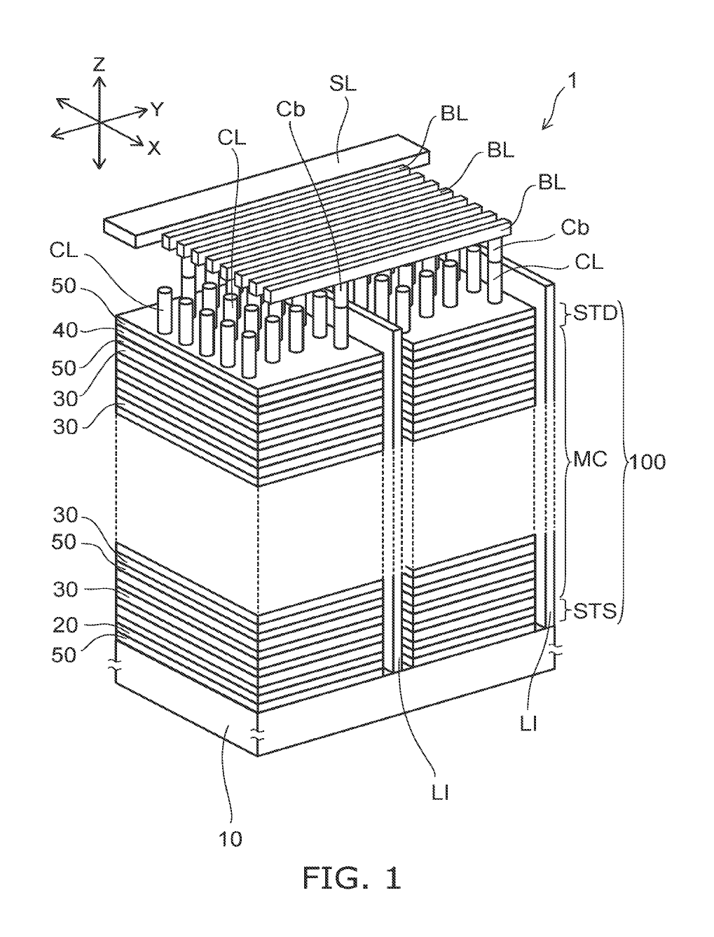

FIG. 1 is a perspective view schematically showing a memory cell array 1 of a non-volatile memory device according to a first embodiment.

As shown in FIG. 1, the memory cell array 1 includes a source layer 10, a stacked body 100 provided on the source layer 10, and upper interconnects provided on the stacked body 100. The upper interconnects are, for example, bit lines BL and a source line SL. The memory cell array 1 further includes a plurality of columnar sections CL and a conductor LI.

The columnar sections CL extend in a first direction (a Z-direction) in the stacked body 100. The columnar sections CL have, for example, a circular, elliptical, or polygonal shape in cross sections perpendicular to the Z-direction. The columnar sections CL are disposed, for example, in zigzag in top view of the stacked body 100. The columnar sections CL may be disposed, for example, at equal intervals in an X-direction and a Y-direction. The conductor LI extends, for example, in the Z-direction and the X-direction between stacked bodies 100 adjacent to each other in a second direction (the Y-direction).

A plurality of bit lines BL and a source line SL are provided on the stacked body 100. For example, each of bit lines BL extends in the Y-direction and is arranged (provided side by side) in the X-direction. For example, the source line SL extends in the Y-direction and is provided in parallel to the bit lines BL.

The columnar sections CL are electrically connected to the bit lines BL via contact sections Cb. Each of the contact sections is in contact with an upper end of a columnar section CL. For example, in a plurality of stacked bodies 100 disposed in the Y-direction, one of columnar sections CL, which extend through a stacked body 100, is electrically connected to one bit line BL. A plurality of columnar sections CL, each of which extends through the different stacked body 100, are electrically connected to the one bit line BL. The lower ends of the columnar sections CL are electrically connected to the source layer 10.

The source layer 10 is electrically connected to the source line SL via the conductor LI. The lower end of the conductor LI is in contact with, for example, the source layer 10. The upper end of the conductor LI is electrically connected to the source line SL in a portion not shown in this figure.

The stacked body 100 includes an electrode layer 20, a plurality of electrode layers 30, an electrode layer 40, and a plurality of insulating layers 50. The electrode layer 20, the plurality of electrode layers 30 and the electrode layer 40 are stacked in the Z-direction in order. The insulating layers 50 are disposed respectively between the source layer 10 and the electrode layer 20, between the electrode layer 20 and the electrode layer 30, between the electrode layers 30 adjacent to each other in the Z-direction, and between the electrode layer 30 and the electrode layer 40. The electrode layers 20, 30, and 40 are metal layers including at least one of tungsten (W), molybdenum (Mo), aluminum (Al), copper (Cu), and ruthenium (Ru), for example. Each of the insulating layers 50 includes, for example, silicon oxide or silicon nitride.

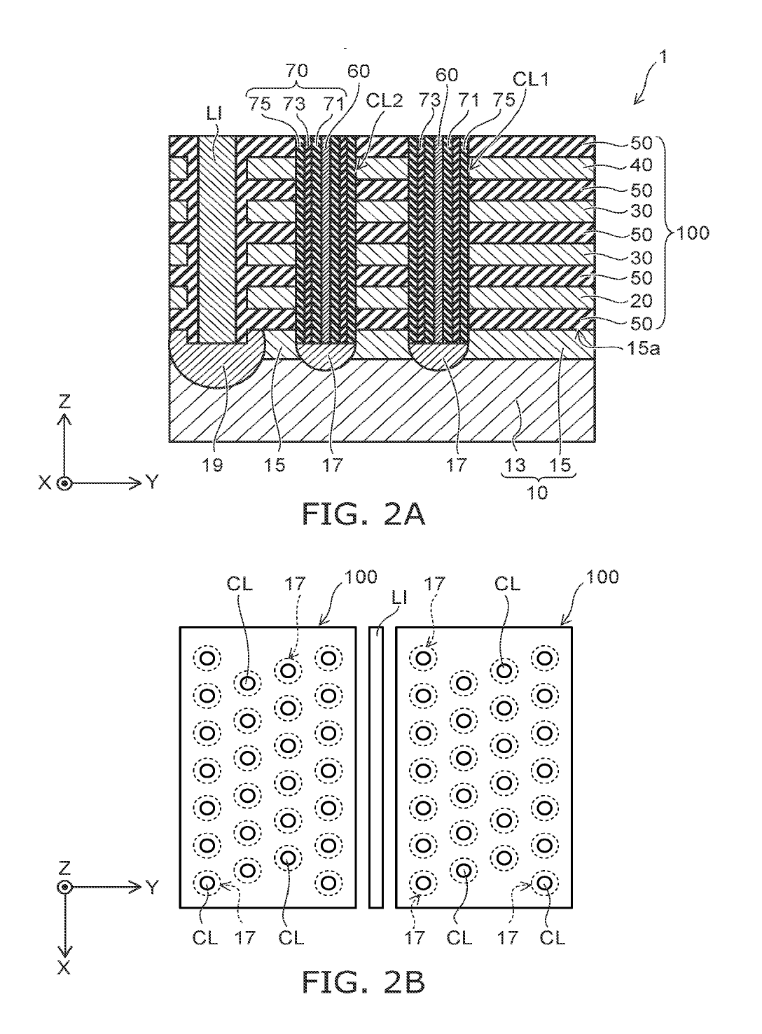

A columnar section CL includes channel body 60 and a memory layer 70 (see FIG. 2). A memory cell MC is provided in a portion where a columnar section CL extends through an electrode layer 30. The electrode layer 30 acts as a control gate of the memory cell MC. A plurality of memory cells MC are disposed in the Z-direction along the columnar section CL. The number of the electrode layers 30 stacked in the Z-direction is equal to the number of the plurality of memory cells MC disposed in the Z-direction.

A selection transistor STS on a source side is provided in a portion where the columnar section CL extends through an electrode layer 20. A selection transistor STD on a drain side is provided in a portion where the columnar section CL extends through an electrode layer 40. A NAND string is provided along the columnar section CL. The NAND strings include the plurality of memory cells MC disposed (provided side by side) in the Z-direction along the columnar section CL, the selection transistors STS and STD. The plurality of the memory cells MC is provided between the selection transistors STS and STD.

FIGS. 2A and 2B are schematic views showing the memory cell array 1. FIG. 2A shows a cross section of the memory cell array 1. FIG. 2B shows an upper surface of the stacked body 100. A simplified structure is shown in FIG. 2A, where the electrode layers 30 and the columnar sections CL are reduced for convenience.

As shown in FIG. 2A, the source layer 10 includes, for example, a p-type conductive layer 13 and an n-type conductive layer 15. The source layer 10 is provided, for example, on a silicon substrate. The p-type conductive layer 13 is, for example, a p-type well provided on the silicon substrate. The n-type conductive layer 15 is, for example, an n-type silicon layer provided on the p-type well.

The stacked body 100 is stacked on the n-type conductive layer 15. The bottom layer of the plurality of insulating layers 50 is provided directly on the n-type conductive layer 15. Columnar sections CL1 and CL2 extend in the Z-direction in the stacked body 100. Each of the columnar sections CL includes the channel body 60 and the memory layer 70. The channel body 60 is a semiconductor layer of silicon or the like. In the specification, a columnar section is individually represented in some cases by the “columnar section CL1” or the “columnar section CL2”, and is comprehensively represented in other cases by the “columnar section CL”. Other component is also represented in the same manner.

The memory layer 70 extends in the Z-direction and includes, for example, tunnel insulating layer 71, charge storage layer 73 and insulative blocking layer 75 which are disposed in order from the channel body 60. The tunnel insulating layer 71 include, for example, at least one of silicon oxide and silicon nitride, and is in contact with the channel body 60.

The charge storage layer 73 includes, for example, at least one of silicon oxide, silicon nitride, polycrystalline silicon and metal. The charge storage layer 73 may have a multilayer structure. In this example, the charge storage layer 73 extends in the Z-direction along the channel body 60. The embodiment, however, is not limited thereto. For example, a plurality of charge storage layers may be discretely disposed in the Z-direction, each of which is provided between an electrode layer 30 and a channel body 60.

The insulative blocking layer 75 includes, for example, at least one of silicon oxide and silicon nitride. The insulative blocking layer 75 may include, for example, metal oxide such as hafnium oxide. The insulative blocking layer 75 may have a multilayer structure, for example.

A memory cell MC is provided in a portion where a columnar section CL extends through the electrode layer 30. The memory cell MC includes a part of the channel body 60, a part of the tunnel insulating layer 71, a part of the charge storage layer 73, a part of the insulative blocking layer 75 and a part of the electrode layer 30. A selection transistor STS is provided in a portion where the columnar section CL extends through the electrode layer 20. The selection transistor STS include another part of the channel body 60, a part of the memory layer 70 and a part of the electrode layer 20. The electrode layer 20 acts as a selection gate electrode. The part of the memory layer 70 acts as a gate insulating layer. A selection transistor STD is provided in a portion where the columnar section CL extends through the electrode layer 40. The selection transistor STD includes other part of the channel body 60, other part of the memory layer 70 and a part of the electrode layer 40. The electrode layer 40 acts as a selection gate electrode. The other part of the memory layer 70 acts as a gate insulating layer.

In this example, the stacked body 100 includes one electrode layer 20 and one electrode layer 40. The embodiment, however, is not limited thereto. For example, the stacked body 100 may include two or more electrode layers 20 or two or more electrode layers 40. That is, the selection transistors STS and STD may respectively include a plurality of selection gates.

The lower end of the columnar section CL is located in the n-type conductive layer 15. The n-type conductive layer 15 preferably has an n-type impurity concentration of 1×10¹⁷ cm⁻³ or more at least in a range from an upper surface 15a thereof to a depth that is a same level as the lower end of the columnar section CL. A p-type region 17 is provided between the lower end of the columnar section CL and the p-type conductive layer 13. The p-type region 17 is in contact with the p-type conductive layer 13 and in contact with the lower end of the channel body 60.

The conductor LI is provided, for example, between the stacked bodies 100 adjacent to each other in the Y-direction. The conductor LI is provided, for example, so as to reach a depth inside the n-type conductive layer 15 from the surface at the same height as the upper surface of the stacked body 100. An n-type contact region 19 is provided between the lower end of the conductor LI and the p-type conductive layer 13. The n-type contact region 19 is in contact with the lower end of the conductor LI and in contact with the n-type conductive layer 15. A maximum value of the n-type impurity concentration of the n-type contact region 19 is larger than a maximum value of the n-type impurity concentration of the n-type conductive layer 15. In other words, a maximum value of the carrier concentration (i.e. the free electron concentration) in the n-type contact region 19 is larger than a maximum value of the carrier concentration in the n-type conductive layer 15.

As shown in FIG. 2B, a plurality of stacked bodies 100 are provided side by side in the Y-direction. For example, the conductor LI is provided between the stacked bodies 100 adjacent to each other in the Y-direction and extends in the X-direction. The plurality of columnar sections CL are provided in each of the stacked bodies 100. The p-type regions 17 are respectively provided under the columnar sections CL. As shown in FIG. 2B, the distance between a columnar section CL and the conductor LI is not constant.

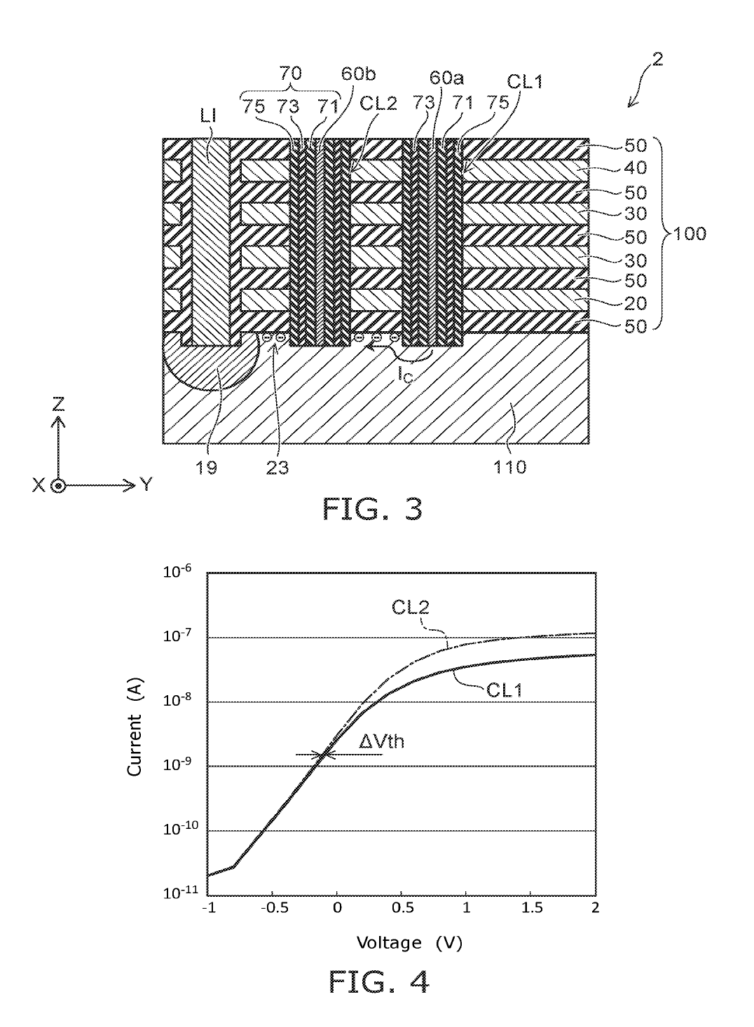

FIG. 3 is a schematic sectional view showing a memory cell array 2 of a non-volatile memory device according to a comparative example. As shown in FIG. 3, in the memory cell array 2, a source layer 110 is provided without the n-type conductive layer 15. The source layer 110 is, for example, a p-type silicon layer.

A columnar section CL extends in the Z-direction in a stacked body 100. The lower end of the columnar section CL is located in the source layer 110. A conductor LI extends in the Z-direction. The lower end of the conductor LI is located in the source layer 110. The lower end of the conductor LI is in contact with the n-type contact region 19 provided in the source layer 110.

A columnar section CL1 shown in FIG. 3 includes a channel body 60a. A columnar section CL2 shown in FIG. 3 includes a channel body 60b. A distance between the columnar section CL1 and the conductor LI is longer than a distance between the columnar section CL2 and the conductor LI. In other words, a distance between the channel body 60a and the conductor LI is longer than a distance between the channel body 60b and the conductor LI.

For example, when data is read out from a memory cell MC, a channel current Ic flows from a channel body 60 to the conductor LI via the source layer 110. In this case, the channel current Ic flows via an inversion layer 23 formed on the source layer 110 side at the interface between the insulating layer 50 and the source layer 110.

The electric resistance between the channel body 60 and the conductor LI changes depending on a distance between a columnar section CL and the conductor LI. That is, the electric resistance between the channel body 60a and the conductor LI is larger than the electric resistance between the channel body 60b and the conductor LI.

FIG. 4 is a graph showing characteristics of the memory cells MC. The vertical axis represents a channel current value (ampere: A) and the horizontal axis represents a voltage (volt: V) of control gates (the electrode layers 30). FIG. 4 shows a characteristic of a memory cell MC provided along the columnar section CL1 and a characteristic of a memory cell MC provided along the columnar section CL2. ΔVth shown in FIG. 4 is a difference between a neutral threshold voltage of the memory cell MC at the columnar section CL1 and a neutral threshold voltage of the memory cell MC at the columnar section CL2.

As shown in FIG. 4, a channel current flowing through the memory cells MC at the columnar section CL1 is smaller than a channel current flowing through the memory cells MC at the columnar section CL2. The difference between the voltages applied to the control gate becomes significant as the channel current value becomes larger.

In the memory cell array 1, it is possible to reduce the electric resistance between the columnar section CL and the conductor LI by providing the n-type conductive layer 15 between the p-type conductive layer 13 and the insulating layer 50. Thus, a difference AVth of the neutral threshold voltage may be suppressed between the memory cells MC at the different columnar sections CL.

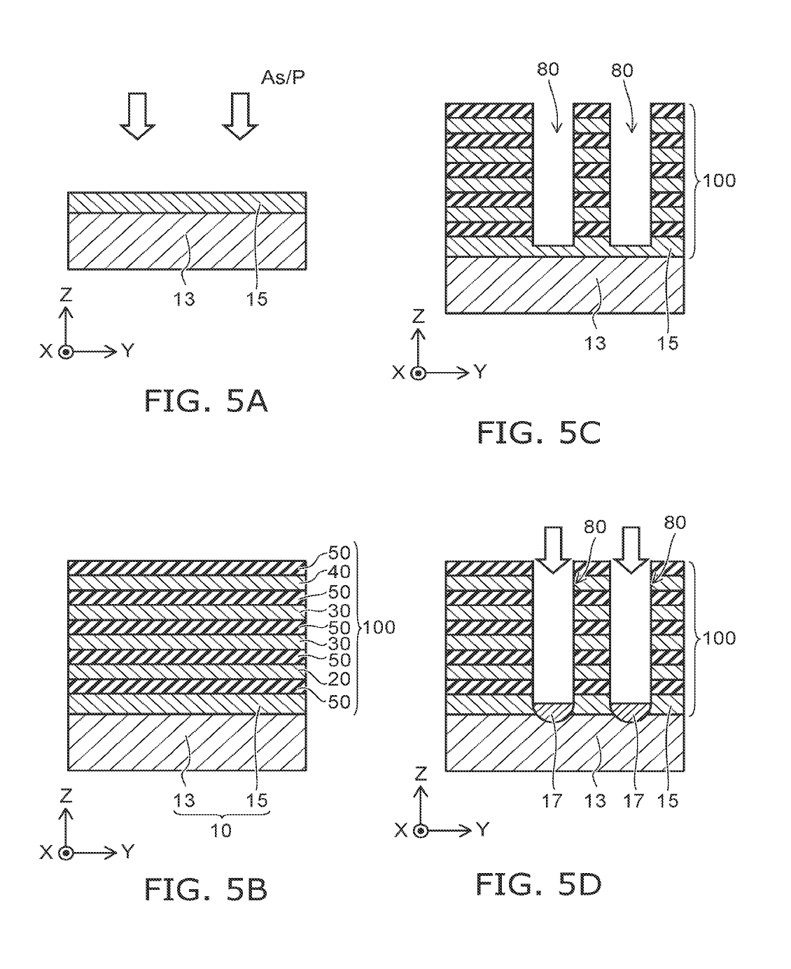

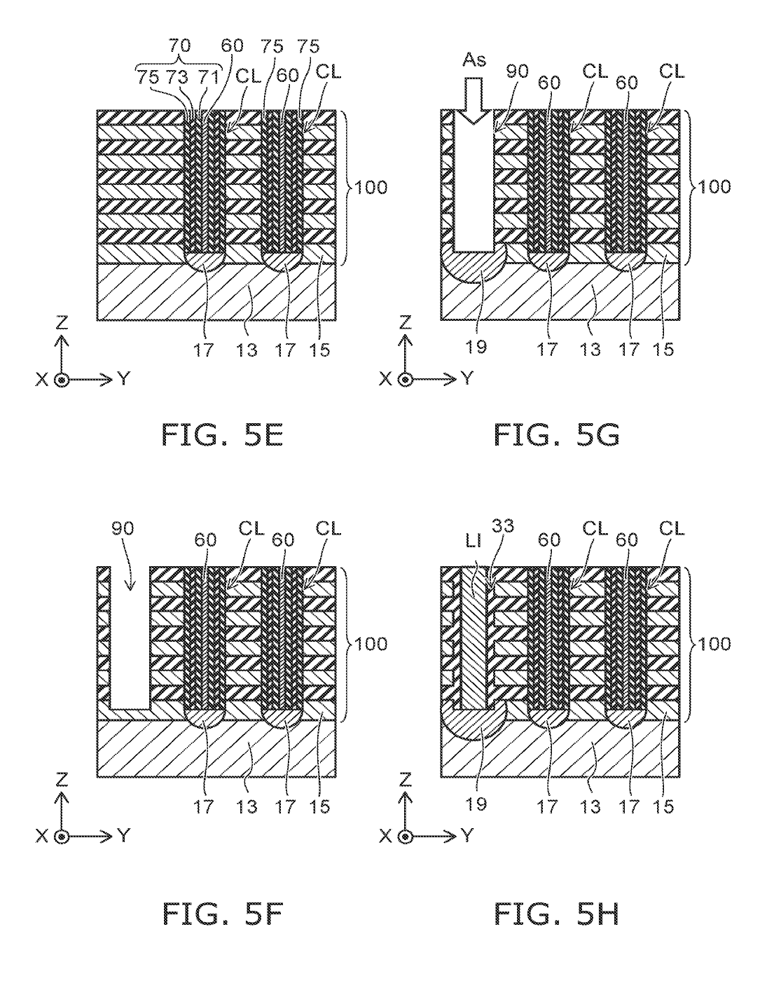

A manufacturing method for the non-volatile memory device according to the first embodiment is described with reference to FIGS. 5A to 5H. FIGS. 5A to 5H are schematic sectional views sequentially showing a manufacturing process of the memory cell array 1.

As shown in FIG. 5A, the n-type conductive layer 15 is formed on the p-type conductive layer 13. For example, boron (B), which is a p-type impurity, is ion-implanted into a silicon substrate (not-shown) to form the p-type conductive layer 13. Thereafter, arsenic (As) or phosphorus (P), which is an n-type impurity, is ion-implanted into the p-type conductive layer 13 to form the n-type conductive layer 15 on the p-type conductive layer 13.

As shown in FIG. 5B, the electrode layers 20, 30, 40 and the insulating layers 50 are stacked on the n-type conductive layer 15. The insulating layers 50 are respectively formed between the n-type conductive layer 15 and the electrode layer 20, between the electrode layer 20 and the electrode layer 30, and between the electrode layer 30 and the electrode layer 40. Note that one electrode layer 30 is shown in FIG. 5B, for convenience. Actually, the same number of the electrode layers 30 is stacked as the number of the memory cells MC disposed in the Z-direction. The insulating layers 50 are also formed between the adjacent electrode layers 30 in the Z-direction. The insulating layer 50 may be formed as the top layer of the stacked body 100.

The electrode layers 20, 30 and 40 are, for example, tungsten (W) layers formed using CVD (Chemical Vapor Deposition). The insulating layers 50 are, for example, silicon oxide layers formed using the CVD.

As shown in FIG. 5C, memory holes 80 are formed so as to extend in the Z-direction in the stacked body 100. Each memory hole 80 is formed with a depth of extending into the n-type conductive layer 15 from the upper surface of the stacked body 100. The memory holes 80 have, for example, a circular or elliptical shape in top view of the stacked body 100. The memory holes 80 are formed using, for example, anisotropic RIE (Reactive Ion Etching).

As shown in FIG. 5D, boron (B), which is the p-type impurity, is ion-implanted into the n-type conductive layer 15 exposed on the bottom surfaces of the memory holes 80 to form the p-type regions 17. For example, after ion-implanting the p-type impurity, the p-type regions 17 are formed to be connected to the p-type conductive layer 13 by heat-treating the silicon substrate to activate and diffuse the p-type impurity.

As shown in FIG. 5E, the columnar sections CL are formed in the memory holes 80. Each of the columnar sections CL includes the memory layer 70 and the channel body 60. For example, the insulative blocking layer 75 is formed to cover an inner surface of a memory hole 80. Subsequently, the charge storage layer 73 is formed on the insulative blocking layer 75. Further, the tunnel insulating layer 71 is formed on the charge storage layer 73.

The insulative blocking layer 75 is, for example, a silicon oxide layer formed using the CVD. The charge storage layer 73 is, for example, a silicon nitride layer formed using the CVD. The tunnel insulating layer 71 is, for example, a silicon oxide layer formed using the CVD.

Subsequently, a part of the memory layer 70 formed on the bottom surfaces of the memory holes 80 is selectively removed. For example, the part of the memory layer 70 on the bottom surfaces of the memory holes 80 are selectively removed using the anisotropic RIE, leaving a part of the memory layers 70 formed on an inner wall of the memory hole 80. In this case, a part of the memory layer 70 formed on the upper surface of the stacked body 100 is also removed.

Subsequently, the channel body 60 is formed to cover the part of the memory layer 70 on the inner wall and the bottom surface of the memory hole 80. The channel body 60 is, for example, a silicon layer formed using the CVD. The channel body 60 is electrically connected to the p-type regions 17 at the bottom surface of the memory holes 80. A part of the silicon layer formed on the upper surface of the stacked body 100 is etched back and removed.

As shown in FIG. 5F, a slit 90 is formed to divide the stacked body 100. The slit 90 is formed, for example, with a depth of extending into the n-type conductive layer 15 from the upper surface of the stacked body 100 using the RIE. The slit 90 is formed in a groove shape extending in the X-direction, for example.

As shown in FIG. 5G, an n-type contact region 19 is formed under the slit 90. The n-type contact region 19 is formed by, for example, ion-implanting an n-type impurity, such as arsenic (As), via the slit 90. A dosage of the n-type impurity is set to form the n-type contact region 19 such that a maximum value of the n-type impurity concentration of the n-type contact region 19 is larger than a maximum value of the n-type impurity concentration of the n-type conductive layer 15.

As shown in FIG. 5H, after an insulating layer 33 is formed to cover the inner surface of the slit 90, the conductor LI is formed. For example, a silicon oxide layer is formed using the CVD to cover the inner surface of the slit 90. Then, for example, a part of the silicon oxide layer deposited on the bottom surface is removed to expose the surface of the n-type contact region 19 by using anisotropic dry etching, leaving a portion deposited on the inner wall of the slit 90. Thereafter, the conductor LI is formed in the slit 90 by embedding tungsten (W), for example. Further, the bit lines BL and the source line SL are formed above the stacked body 100 and the conductor LI to complete the memory cell array 1.

The source layer 10 according to the embodiment includes the p-type conductive layer 13 and the n-type conductive layer 15. The n-type conductive layer 15 is provided between the stacked body 100 and the p-type conductive layer 13, and reduces the electric resistance between the channel bodies 60 and the conductor LI. Consequently, it is possible to suppress variations of the neutral threshold voltage among the memory cells MC provided in the different columnar sections CL. A p-type region 17 is provided between the p-type conductive layer 13 and a channel body 60. The p-type regions 17 acts as a pathway of hole transport between the p-type conductive layer 13 and the channel body 60. Thus, it is possible to inject the holes into the channel body 60 when erasing data in the memory cell MC and to improve efficiency of the data erasing.

### Second Embodiment

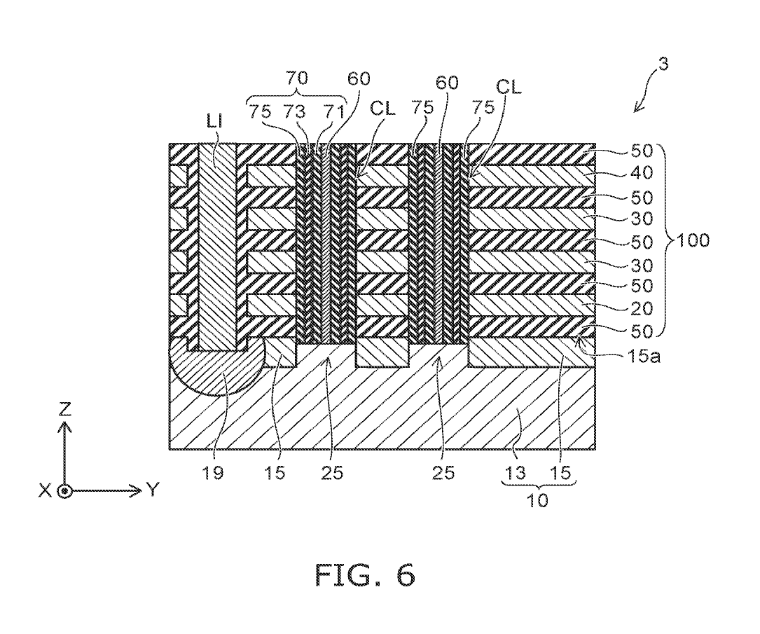

FIG. 6 is a schematic sectional view showing a memory cell array 3 of a non-volatile memory device according to a second embodiment. FIG. 6 shows a sectional structure simplified for convenience by reducing the electrode layers 30 and the columnar sections CL.

As shown in FIG. 6, the source layer 10 includes, for example, the p-type conductive layer 13 and the n-type conductive layer 15. The stacked body 100 is stacked on the n-type conductive layer 15. A plurality of columnar sections CL are provided in the stacked body 100. A columnar section CL includes a channel body 60 and a memory layer 70.

The memory layer 70 extends in the Z-direction and includes, from the channel body 60, for example, a tunnel insulating layer 71, a charge storage layer 73, and an insulative blocking layer 75. The tunnel insulating layer 71 is, for example, a silicon oxide layer and is in contact with the channel body 60. The charge storage layer 73 is, for example, a silicon nitride layer. The insulative blocking layer 75 is, for example, a silicon oxide layer. The insulative blocking layer 75 may be a metal oxide layer of hafnium oxide or the like.

A memory cell MC is provided in a portion where the columnar section CL extends through an electrode layer 30. The selection transistors STS and STD are respectively provided in portions where the columnar section CL extends through the electrode layers 20 and 40.

The lower end of the columnar section CL is located in the n-type conductive layer 15. The n-type conductive layer 15 preferably has n-type impurity concentration of 1×10¹⁷ cm⁻³ or more at least in a range from the upper surface 15a thereof to a depth at the same level as the lower end of the columnar section CL. A p-type region 25 is provided between the lower end of the columnar section CL and the p-type conductive layer 13. The p-type region 25 includes, for example, silicon epitaxially grown on the p-type conductive layer 13. The channel body 60 is provided such that the lower end thereof is in contact with the p-type region 25.

The conductor LI is provided, for example, between the adjacent stacked bodies 100 in the Y-direction. The conductor LI is provided, for example, with a length of extending in the n-type conductive layer 15 from a surface thereof at the same level as the upper surface of the stacked body 100. The n-type contact region 19 is provided between the lower end of the conductor LI and the p-type conductive layer 13. The n-type contact region 19 is in contact with the lower end of the conductor LI and in contact with the n-type conductive layer 15. A maximum value of the n-type impurity concentration in the n-type contact region 19 is larger than a maximum value of the n-type impurity concentration in the n-type conductive layer 15.

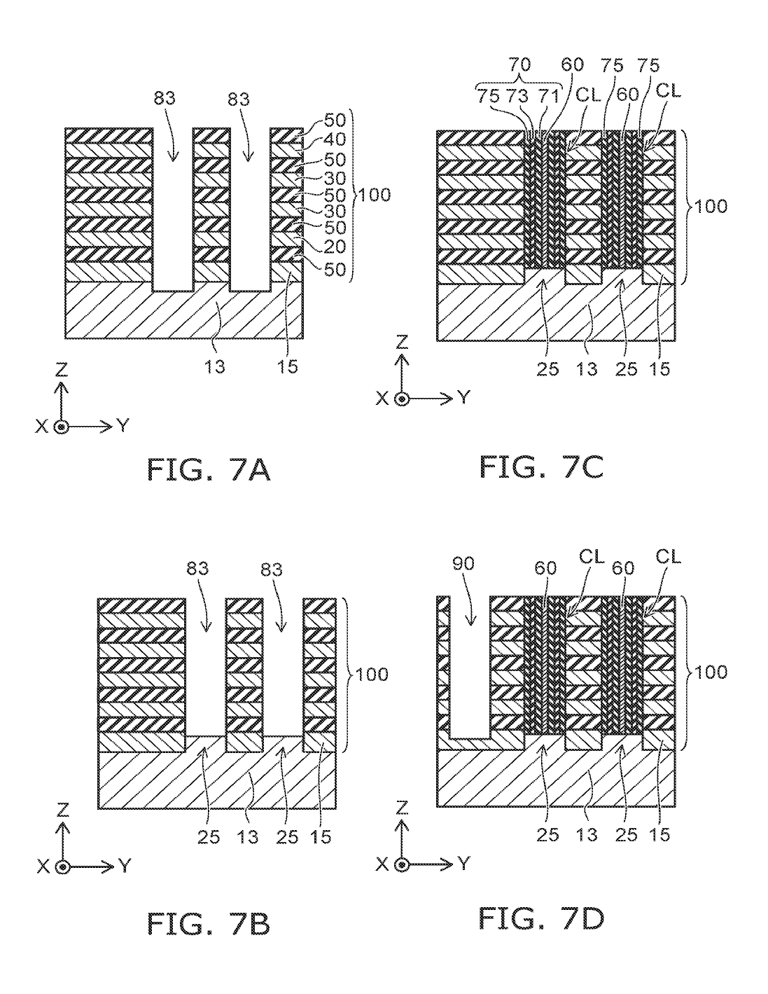

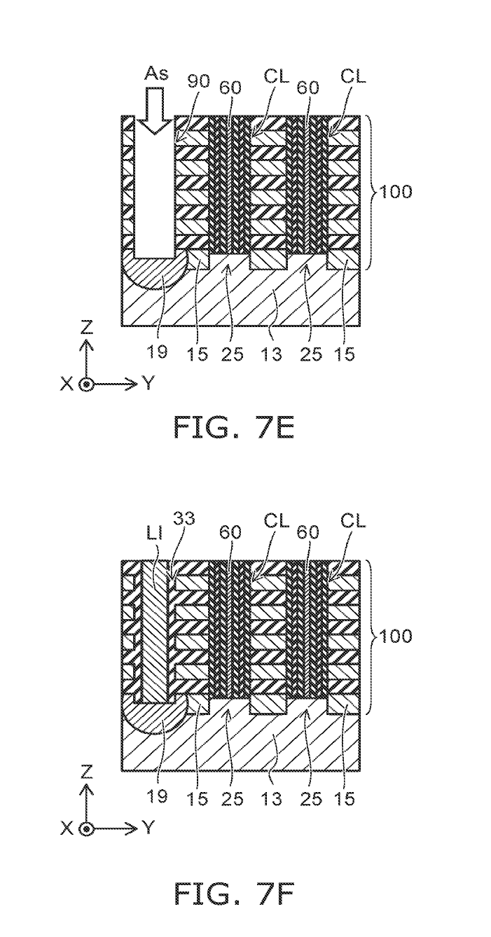

A manufacturing method for the non-volatile memory device according to the second embodiment is described with reference to FIGS. 7A to 7F. FIGS. 7A to 7F are schematic sectional views showing a manufacturing process following FIG. 5B.

As shown in FIG. 7A, memory holes 83 are formed to extend in the Z-direction in the stacked body 100. Each of the memory holes 83 is formed with a depth of extending into the p-type conductive layer 13 from the upper surface of the stacked body 100. The memory holes 83 have, for example, a circular or elliptical shape in top view of the stacked body 100. The memory holes 83 are formed using, for example, anisotropic RIE.

As shown in FIG. 7B, a p-type region 25 is formed at a bottom of a memory hole 83. For example, p-type semiconductors are epitaxially grown on the p-type conductive layer 13 and the n-type conductive layer 15 exposed on a surface of a bottom portion of the memory hole 83. The p-type conductive layer 13 and the n-type conductive layer 15 are, for example, silicon layers. Thus, p-type silicon can be epitaxially grown thereon. In this case, it is preferable to select a growth condition under which no silicon is deposited on the electrode layers 20, 30, 40 and the insulating layers 50 exposed on the inner wall of the memory hole 83.

As shown in FIG. 7C, a columnar section CL is formed in a memory hole 83. The columnar section CL includes the memory layer 70 and the channel body 60. For example, the insulative blocking layer 75 is formed to cover the inner surface of the memory hole 83. Subsequently, the charge storage layer 73 is formed on the insulative blocking layer 75. Further, the tunnel insulating layer 71 is formed on the charge storage layer 73.

Subsequently, parts of the memory layer 70 formed on the upper surface of the p-type region 25 and the upper surface of the stacked body 100 are selectively removed. Then, the channel body 60 is formed on the p-type region 25 and the memory layer 70 covering the inner walls of the memory holes 83. The channel body 60 is, for example, a silicon layer formed using the CVD. The channel body 60 is formed in contact with the p-type region 25.

As shown in FIG. 7D, a slit 90 is formed to divide the stacked body 100. The slit 90 is formed, for example, with a depth of extending into the n-type conductive layer 15 from the upper surface of the stacked body 100 using RIE. The slit 90 is formed in a groove shape extending in the X-direction, for example.

As shown in FIG. 7E, an n-type contact region 19 is formed under the slit 90. The n-type contact region 19 is formed by, for example, ion-implanting an n-type impurity, such as arsenic (As). A dosage of the n-type impurity is set to form the n-type contact region 19 such that a maximum value of the n-type impurity concentration in the n-type contact region 19 is larger than a maximum value of the n-type impurity concentration in the n-type conductive layer 15.

As shown in FIG. 7F, the conductor LI is formed after an insulating layer 33 is formed to cover the inner surface of the slit 90. For example, a silicon oxide layer is formed using the CVD to cover the inner wall of the slit 90. Then, the conductor LI is formed in the slit 90. The conductor LI includes, for example, tungsten (W). Further, bit lines BL and a source line SL are formed above the stacked body 100 and the conductor LI to complete the memory cell array 3.

In the embodiment, the n-type conductive layer 15 reduces the electric resistance between the channel body 60 and the conductor LI and suppresses variations of the neutral threshold voltage among the memory cells MC provided in the different columnar sections CL. By interposing the p-type region 25 between the p-type conductive layer 13 and the channel body 60, it is possible to inject holes into the channel body 60 when erasing data of the memory cells MC, thereby improving efficiency of the data erasing.

### Third Embodiment

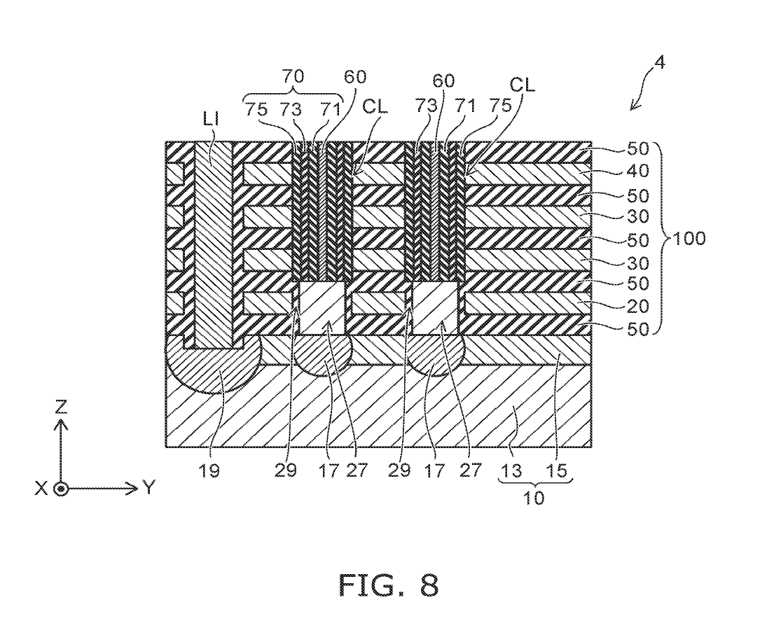

FIG. 8 is a schematic sectional view showing a memory cell array 4 according to a third embodiment. FIG. 8 shows a sectional structure simplified for convenience by reducing the electrode layers 30 and the columnar sections CL.

As shown in FIG. 8, the source layer 10 includes, for example, the p-type conductive layer 13, the n-type conductive layer 15 and the p-type regions 17. The stacked body 100 is stacked on the n-type conductive layer 15. A maximum value of the n-type impurity concentration in the n-type conductive layer 15 is preferably 1×10¹⁷ cm⁻³ or more.

A plurality of columnar sections CL are provided in the stacked body 100. A columnar section CL includes the channel body 60 and the memory layer 70. The columnar section CL is provided with a length of reaching a level between the electrode layer 20 and a bottom layer of the plurality of electrode layers 30 from the upper surface of the stacked body 100.

A p-type region 17 is provided in the n-type conductive layer 15 and locates at a position capable of electrically connecting the p-type conductive layer 13 and the channel body 60. A gate channel section 27 is provided between the columnar section CL and the p-type region 17. The gate channel section 27 includes, for example, a semiconductor epitaxially grown on the p-type regions 17. The gate channel section 27 is provided so as to extend through the electrode layer 20. The gate channel section 27 is in contact with the lower end of the columnar section CL and in contact with the upper surfaces of the p-type region 17. A gate insulating layer 29 is provided between the electrode layer 20 and the gate channel section 27.

A memory cell MC is provided in a portion where the columnar section CL extends through the electrode layer 30. A selection transistor STD is provided in a portion where the columnar section CL extends through the electrode layer 40. A selection transistor STS is provided in a portion where the gate channel section 27 extends through the electrode layer 20.

A conductor LI is provided, for example, between the adjacent stacked bodies 100 in the Y-direction. The conductor LI is provided, for example, with a length of extending into the n-type conductive layer 15 from the surface thereof at the same level as the upper surface of the stacked body 100. The n-type contact region 19 is provided between the lower end of the conductor LI and the p-type conductive layer 13. The n-type contact region 19 is in contact with the lower end of the conductor LI and in contact with the n-type conductive layer 15. A maximum value of the n-type impurity concentration in the n-type contact region 19 is larger than a maximum value of the n-type impurity concentration in the n-type conductive layer 15.

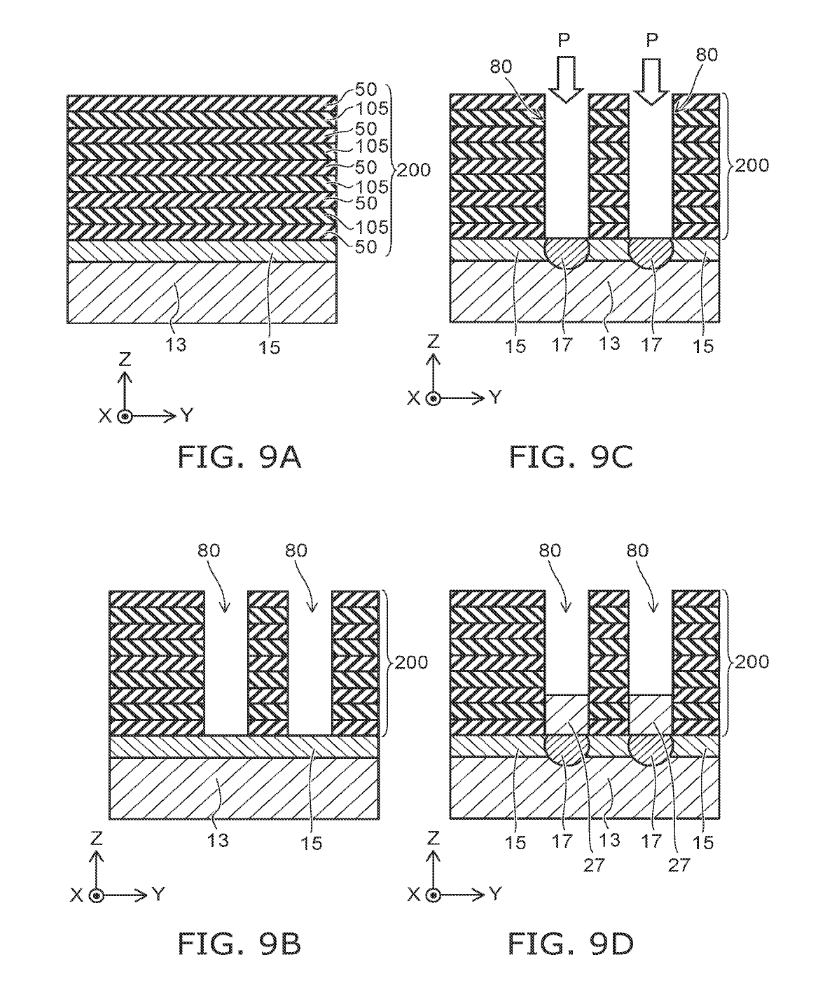

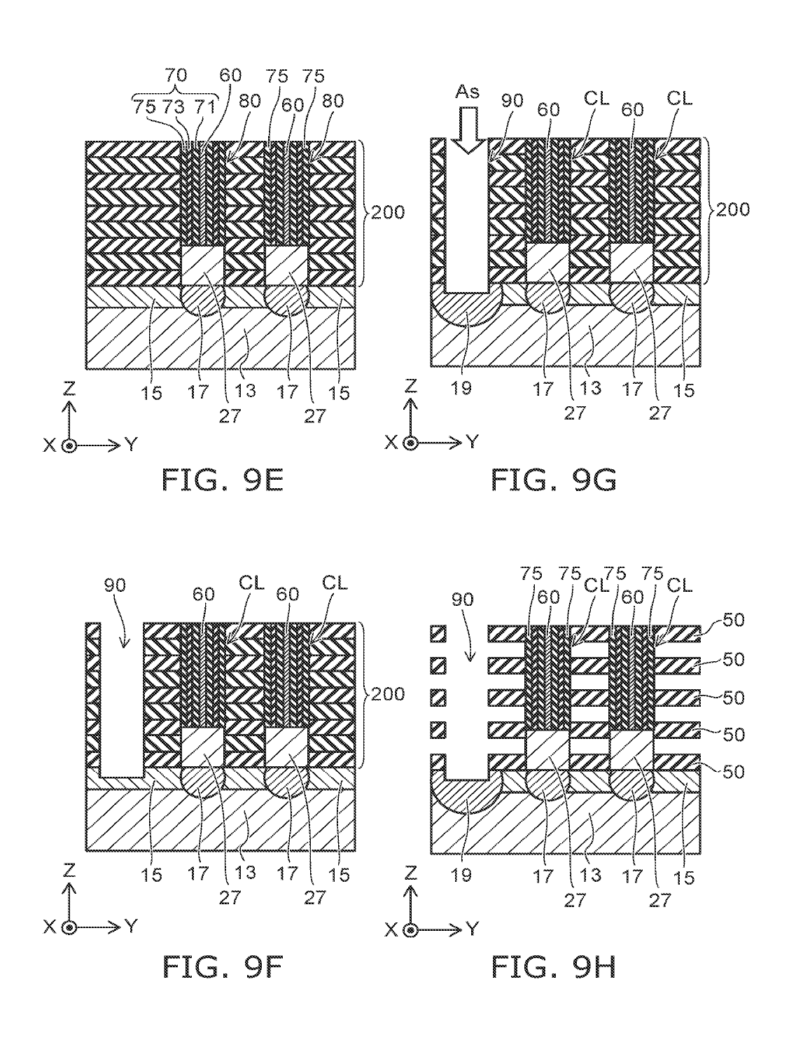

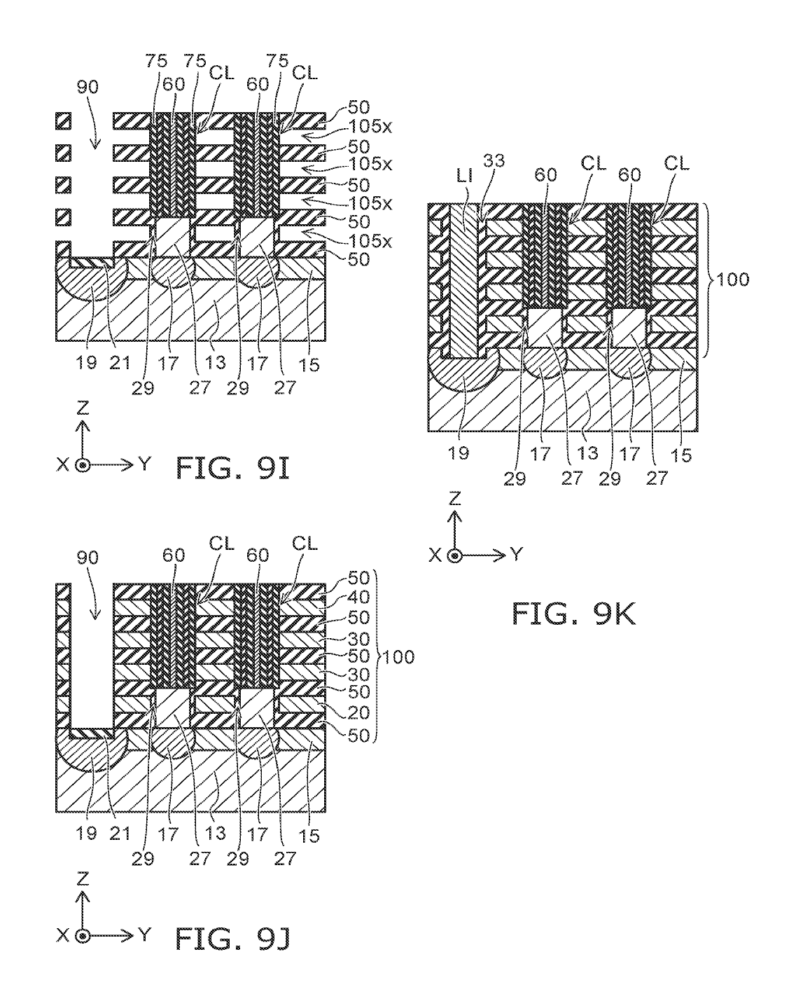

A manufacturing method for the non-volatile memory device according to the third embodiment is described with reference to FIGS. 9A to 9K. FIGS. 9A to 9K are schematic sectional views showing a manufacturing process following FIG. 5A.

As shown in FIG. 9A, a stacked body 200 is formed to include the insulating layers 50 and sacrificial layers 105. The insulating layers 50 and the sacrificial layers 105 are alternately stacked on the n-type conductive layer 15. The insulating layers 50 are, for example, silicon oxide layers formed using CVD. The sacrificial layers 105 are, for example, silicon nitride layers formed using CVD. A sacrificial layer 105 is made of a material having selectivity of etching against an insulating layer 50. That is, it is preferable to use a material capable of being etched with larger rate for the sacrificial layers 105 than an etching rate of the insulating layers 50.

As shown in FIG. 9B, the memory holes 80 are formed to extend in the Z-direction in the stacked body 200. Each of the memory holes 80 is formed with a depth of extending in the n-type conductive layer 15 from the upper surface of the stacked body 200. The memory holes 80 have, for example, a circular or elliptical shape in top view of the stacked body 200. The memory holes 80 are formed using, for example, anisotropic RIE.

As shown in FIG. 9C, the p-type impurity such as boron (B) is ion-implanted into the n-type conductive layer 15 exposed on the bottom surface of a memory hole 80 to form a p-type region 17. For example, after ion-implanting the p-type impurity, the p-type regions 17 are formed to be connected to the p-type conductive layer 13 by heat-treating the silicon substrate to activate and diffuse the p-type impurity.

As shown in FIG. 9D, a gate channel section 27 is formed in a bottom of a memory hole 80. A semiconductor is epitaxially grown on the p-type conductive layer 13 exposed on the bottom surface of the memory holes 80. The p-type conductive layer 13 is, for example, a silicon layer. Thus, silicon can be epitaxially grown on the p-type conductive layer 13. In this case, it is preferable to select a growth condition under which no silicon is deposited on the insulating layers 50 and the sacrificial layers 105 exposed on the inner wall of the memory hole 80.

As shown in FIG. 9E, a columnar section CL is formed in a memory hole 80. The columnar section CL includes the memory layer 70 and the channel body 60. For example, an insulative blocking layer 75 is formed to cover the inner surface of the memory hole 80. Subsequently, a charge storage layer 73 is formed on the insulative blocking layer 75. Further, the tunnel insulating layer 71 is formed on the charge storage layer 73.

Subsequently, parts of the memory layer 70 formed on the bottom surface of the memory hole 80 and the upper surface of the stacked body 200 are selectively removed. Then, a channel body 60 is formed to cover the bottom surface of the memory hole 80 and the memory layer 70 on the inner wall of the memory hole 80. The channel body 60 is, for example, a silicon layer formed using CVD. The channel body 60 is in contact with the gate channel section 27 at the lower end thereof.

As shown in FIG. 9F, a slit 90 is formed to divide the stacked body 200. The slit 90 is formed, for example, with a depth of extending in the n-type conductive layer 15 from the upper surface of the stacked body 200 using RIE. The slit 90 is formed in a groove shape extending in the X-direction, for example.

As shown in FIG. 9G, an n-type contact region 19 is formed under the slit 90. The n-type contact region 19 is formed by, for example, ion-implanting an n-type impurity, such as arsenic (As). A dosage of the n-type impurity is set to form the n-type contact region 19 such that a maximum value of the n-type impurity concentration in the n-type contact region 19 is larger than a maximum value of the n-type impurity concentration in the n-type conductive layer 15.

As shown in FIG. 9H, the sacrificial layers 105 are selectively removed. For example, etching liquid is supplied via the slit 90, which can selectively remove the sacrificial layers 105 against the insulating layers 50 and the n-type contact region 19. For example, the sacrificial layers 105 includes silicon nitride, and can be removed using hot phosphoric acid.

As shown in FIG. 9I, a gate insulating layer 29 is formed on a surfaces of the gate channel section 27 exposed to a space 105x formed after the sacrificial layers 105 are removed. For example, the gate channel section 27 are thermally oxidized, and silicon oxide layer is formed on the surfaces thereof. In this case, the insulating layer 21 is also formed on a surface of the n-type contact region 19.

As shown in FIG. 93, the electrode layers 20, 30 and 40 are formed in the spaces 105x that are formed by removing the sacrificial layers 105. The electrode layers 20, 30 and 40 are, for example, metal layers of tungsten or the like formed using CVD. Source gases of CVD are supplied to the spaces 105x, for example, via the slit 90. Thus, the stacked body 100 is formed, which includes the electrode layers 20, 30 and 40.

As shown in FIG. 9K, a conductor LI is formed in the slit 90. For example, after the metal layer deposited on the inner surface of the slit 90 is removed, the insulating layer 33 is formed using CVD to cover the inner surface of the slit 90. In this case, the insulating layer 21 formed on the n-type contact region 19 is joined with the insulating layer 33. Further, the insulating layer 33 formed on the bottom surface of the slit 90 is selectively removed to expose the surface of the n-type contact region 19. That is, the silicon oxide layer deposited on the bottom surface is removed leaving a portion deposited on the inner wall of the slit 90, for example, using anisotropic dry etching. Then, the conductor LI is formed by, for example, embedding tungsten (W) in the slit 90. Subsequently, bit lines BL and a source line SL are formed above the stacked body 100 and the conductor LI to complete the memory cell array 4.

In the embodiment, the n-type conductive layer 15 reduces the electric resistance between the gate channel sections 27 and the conductor LI, and suppresses variations of the neutral threshold voltages among the memory cells MC provided in the different columnar sections CL. It is possible to inject holes into the channel body 60 while erasing data of the memory cells MC, and to improve efficiency of the data erasing by interposing the p-type region 17 between the p-type conductive layer 13 and the gate channel section 27.

### Fourth Embodiment

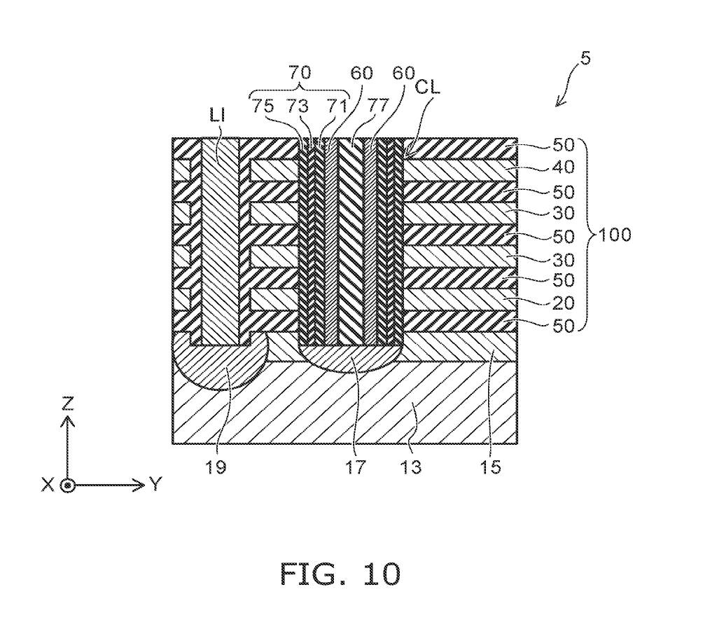

FIG. 10 is a schematic sectional view showing a memory cell array 5 according to a fourth embodiment. FIG. 10 shows a sectional structure simplified for convenience by reducing the electrode layers 30 and the columnar sections CL.

As shown in FIG. 10, a source layer 10 includes, for example, a p-type conductive layer 13, an n-type conductive layer 15, a p-type region 17 and an n-type contact region 19. A stacked body 100 is stacked on the n-type conductive layer 15. A maximum value of the n-type impurity concentration in the n-type conductive layer 15 is preferably 1×10¹⁷ cm⁻³ or more.

A columnar section CL is provided in the stacked body 100. The columnar section CL includes a channel body 60, a memory layer 70, and a core 77. The columnar section CL is provided so as to extend into the n-type conductive layer 15 from the upper surface of the stacked body 100. The p-type region 17 is provided at the lower end of the columnar section CL in the n-type conductive layer 15 and electrically connect the p-type conductive layer 13 and the channel body 60.

The memory layer 70 is provided between each electrode layer and the channel body 60. The memory layer 70 includes a tunnel insulating layer 71, a charge storage layer 73, and an insulative blocking layer 75. The core 77 is formed on the channel body 60 in the memory holes 80 (see FIG. 5C) and fills a space in the memory holes 80. The core 77 is an insulator such as silicon oxide.

The channel bodies 60 are provided between the memory layer 70 and the core 77. The channel body 60 and the memory layer 70 are provided to surround the core 77 in top view of the stacked body 100. In other words, the channel body 60 and the memory layer 70 are disposed, for example, in concentric shapes centering on the core 77.

A memory cell MC is provided in a portion where the columnar section CL extends through an electrode layer 30. The selection transistor STD is provided in a portion where the columnar section CL extends through the electrode layer 40. The selection transistor STS is provided in a portion where the columnar section CL extends through the electrode layer 20.

The first, second, third, and fourth embodiments are described above. However, embodiments are not limited thereto. The components indicated by the same reference numerals and signs are common to each other and may provide the same advantages in the embodiments. Further, a component described in one of the embodiments may be applicable to other embodiments when technically possible.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A non-volatile memory device comprising:
a first conductive layer of a first conductivity type;
a second conductive layer of a second conductivity type provided on the first conductive layer;
a first electrode layer stacked with the second conductive layer in a first direction;
a first channel body extending through the first electrode layer in the first direction;
a charge storage layer provided between the first electrode layer and the first channel body;
a first region of the first conductivity type provided locally in the second conductive layer between the first conductive layer and the first channel body, the first channel body being electrically connected to the first conductive layer through the first region; and
a conductor extending through the first electrode in the first direction and electrically connected to the second conductive layer.

2. The device according to claim 1, further comprising:
a first insulating layer provided between the charge storage layer and the first channel body; and
a second insulating layer extending in the first direction along the first channel body, a part of the second insulating layer being located between the first electrode and the charge storage layer, an end of the first channel body being in contact with the first region, and
an end of the second insulating layer being located in the second conductive layer.

3. The device according to claim 2, wherein the second conductive layer has an impurity concentration of the second conductivity type of 1×10¹⁷ cm⁻³ or more in a range from the surface opposite to the first conductive layer to a depth at the same level as a level of the end of the second insulating layer.

4. The device according to claim 2, wherein the first insulating layer includes at least one of silicon oxide and silicon nitride.

5. The device according to claim 2, wherein the second insulating layer includes at least one of silicon oxide and silicon nitride.

6. The device according to claim 5, wherein the second insulating layer has a multilayer structure.

7. The device according to claim 1, further comprising:
a second region of the second conductivity type provided in the second conductive layer, the second region being in contact with the conductor, and having a maximum value of carrier concentration larger than a maximum value of carrier concentration in the second conductive layer.

8. The device according to claim 1, wherein the charge storage layer includes at least one of silicon oxide, silicon nitride, polycrystalline silicon and metal.

9. The device according to claim 8, wherein the charge storage layer has a multilayer structure.

10. The device according to claim 1, further comprising:
a second electrode layer provided between the first electrode layer and the second conductive layer;
a second channel body provided between the first channel body and the first region, a second channel body extending through the second electrode layer, and being in contact with the first channel body and the first region; and
a third insulating layer provided between the second electrode layer and the second channel body.

11. The device according to claim 10, wherein
the second channel body includes silicon, and
the third insulating layer includes silicon oxide.

12. The device according to claim 10, wherein the second conductive layer has a maximum value of second conductivity type impurity concentration of 1×10¹⁷ cm⁻³ or more.

13. The device according to claim 1, further comprising:
a first interconnect arranged with the conductor in the first direction, the conductor being provided between the first interconnect and the second conductive layer, and electrically connected to the first interconnect and the second conductive layer.

14. The device according to claim 1, further comprising:
a second interconnect arranged with the first electrode layer in the first direction, the first electrode layer being provided between the second interconnect and the second conductive layer, and the first channel body being electrically connected to the second interconnect.
